(19) United States
(12) Patent Application Publication
(10) Pub. No.: US 2024/0170600 A1
(43) Pub. Date: May 23, 2024

(54) HgZnTe DETECTOR ON SILICON SUBSTRATE

(71) Applicant: Raytheon Company, Tewksbury, MA (US)

(72) Inventor: Jeffrey M. Peterson, Santa Barbara, CA (US)

(73) Assignee: Raytheon Company, Tewksbury, MA (US)

(21) Appl. No.: 18/511,581

(22) Filed: Nov. 16, 2023

Related U.S. Application Data
(60) Provisional application No. 63/384,132, filed on Nov. 17, 2022.

(51) Int. Cl. H01L 31/103; H01L 31/0296; H01L 31/18

(52) U.S. Cl. CPC H01L 31/1032; H01L 31/02966; H01L 31/1832

(57) ABSTRACT

A HgZnTe detector on a silicon substrate provides significant advantages over conventionally used HgCdTe detectors on silicon substrates, as HgZnTe is a harder material than HgCdTe, and has less lattice mismatch with silicon than HgCdTe. HgZnTe also has a higher dislocation energy than HgCdTe, as well as a higher thermal stability than HgCdTe, making it more resistant to dislocation.

### RELATED APPLICATION

This application claims the benefit of U.S. Provisional Application No. 63/384,132, filed Nov. 17, 2022, which is hereby incorporated herein by reference in its entirety.

### TECHNICAL FIELD

The present disclosure relates generally to focal plane arrays, and more particularly to detectors on substrates of focal plane arrays.

### BACKGROUND

Silicon substrates are typically used for large area focal plane arrays due to the large diameter of the wafer. Typically, molecular-beam epitaxy (MBE) grown HgCdTe infrared (IR) detectors are used on silicon substrates. As depicted in FIG. 1, for example, a conventionally known detector assembly 10 configured to be used in a conventional focal plane array uses a HgCdTe detector 12 on a silicon substrate 14. The silicon substrate 14 may include, specifically, a silicon layer 16, a ZnTe layer 18 and a CdTe layer 20. However, reduced performance of such HgCdTe detectors 12 is observed due to dislocation density (EPD). That is, detector performance of such HgCdTe detectors 12 on silicon substrates 16 is degraded by dislocations or crystalline imperfections created by the significant lattice mismatch between silicon and HgCdTe. Additionally, as HgCdTe is a significantly softer material than silicon, HgCdTe plastically deforms, causing the dislocation density to increase.

### SUMMARY

A HgZnTe detector on a substrate, for example a silicon substrate, is described herein and provides significant advantages over conventionally used HgCdTe detectors on silicon substrates. Specifically, HgZnTe is a physically harder material than HgCdTe. As depicted in FIG. 2, HgZnTe has up to twice the mechanical strength as HgCdTe in a range of wavelengths. This makes HgZnTe more mechanically resistant to deformation. Additionally, as depicted in FIG. 3, the lattice parameter of HgZnTe (represented by the line diagonal connecting the lattice parameters of HgTe and ZnTe) is closer than the lattice parameter of HgCdTe (represented by the straight line connecting the lattice parameters of HgTe and CdTe) to the lattice parameter of silicon. This results in less of a lattice mismatch between HgZnTe and silicon than HgCdTe and silicon, resulting in less detector deformation of a HgZnTe detector on silicon than a HgCdTe detector on silicon. Moreover, HgZnTe has a higher dislocation energy than HgCdTe, as well as a higher thermal stability than HgCdTe, also making it more resistant to dislocation. Due to the advantageous material properties of HgZnTe detectors over HgCdTe detectors, a detector assembly using an HgZnTe detector enables a direct bond interconnect of a 200 mm diameter HgZnTe/Si wafer to read out integrated circuit (ROIC) wafers, as it is more compatible with the direct bond interconnect process.

Therefore, according to an aspect of this disclosure, a detector assembly includes a silicon substrate, a HgZnTe-based buffer layer grown on the silicon substrate, and a HgZnTe detector grown on the HgZnTe-based buffer layer.

According to an embodiment of any paragraph(s) of this disclosure, the silicon substrate includes a silicon layer, a ZnTe layer and a CdTe layer.

According to another embodiment of any paragraph(s) of this disclosure, the detector assembly further includes a passivation layer.

According to another embodiment of any paragraph(s) of this disclosure, the passivation layer includes ZnTe.

According to another embodiment of any paragraph(s) of this disclosure, any one of the HgZnTe-based buffer layer, the HgZnTe detector and the passivation layer are grown using molecular-beam epitaxy.

According to another embodiment of any paragraph(s) of this disclosure, the HgZnTe-based buffer layer includes a strained layer superlattice of HgZnTe.

According to another embodiment of any paragraph(s) of this disclosure, the HgZnTe-based buffer layer includes a strained layer superlattice of at least one short-wave HgZnTe superlattice layer and at least one short-medium wave HgZnTe superlattice layer.

According to another embodiment of any paragraph(s) of this disclosure, the HgZnTe-based buffer layer includes a strained layer superlattice of a plurality of short-wave HgZnTe superlattice layers respectively alternating with a plurality of short-medium wave HgZnTe superlattice layers.

According to another embodiment of any paragraph(s) of this disclosure, the HgZnTe-based buffer layer includes a strained layer superlattice of at least one short-wave HgZnTe superlattice layer and at least one medium-wave HgZnTe superlattice layer.

According to another embodiment of any paragraph(s) of this disclosure, the HgZnTe-based buffer layer includes a strained layer superlattice of a plurality of short-wave HgZnTe superlattice layers respectively alternating with a plurality of medium-wave HgZnTe superlattice layers.

According to another embodiment of any paragraph(s) of this disclosure, the HgZnTe-based buffer layer includes a superlattice of at least one HgZnTe superlattice layer and at least one HgCdTe superlattice layer.

According to another embodiment of any paragraph(s) of this disclosure, the HgZnTe-based buffer layer includes a superlattice of a plurality of HgZnTe superlattice layers respectively alternating with a plurality of HgCdTe superlattice layers.

According to another aspect of this disclosure, a method of forming a detector assembly includes the steps of providing a silicon substrate, growing a HgZnTe-based buffer layer on the silicon substrate, and growing a HgZnTe detector on the HgZnTe-based buffer layer.

According to an embodiment of any paragraph(s) of this disclosure, the HgZnTe-based buffer layer is grown on the silicon substrate using molecular-beam epitaxy.

According to another embodiment of any paragraph(s) of this disclosure, the HgZnTe detector is grown on the HgZnTe-based buffer layer using molecular-beam epitaxy.

According to another embodiment of any paragraph(s) of this disclosure, the method further includes the step of growing a passivation layer on the HgZnTe detector.

According to another embodiment of any paragraph(s) of this disclosure, the passivation layer is grown on the HgZnTe detector using molecular-beam epitaxy.

According to another embodiment of any paragraph(s) of this disclosure, the growing the HgZnTe-based buffer layer on the silicon substrate includes growing a strained layer superlattice of at least one short-wave HgZnTe superlattice layer and at least one short-medium wave HgZnTe superlattice layer.

According to another embodiment of any paragraph(s) of this disclosure, the growing the HgZnTe-based buffer layer on the silicon substrate includes growing a strained layer superlattice of at least one short-wave HgZnTe superlattice layer and at least one medium-wave HgZnTe superlattice layer.

According to another embodiment of any paragraph(s) of this disclosure, the growing the HgZnTe-based buffer layer on the silicon substrate includes growing a superlattice of at least one HgZnTe superlattice layer and at least one HgCdTe superlattice layer.

The following description and the annexed drawings set forth in detail certain illustrative embodiments described in this disclosure. These embodiments are indicative, however, of but a few of the various ways in which the principles of this disclosure may be employed. Other objects, advantages and novel features will become apparent from the following detailed description when considered in conjunction with the drawings.

### BRIEF DESCRIPTION OF DRAWINGS

The annexed drawings show various aspects of the disclosure.

FIG. 1 is a schematic diagram of a conventional detector assembly.

FIG. 2 is a graph showing microhardness of materials.

FIG. 3 is a graph showing lattice parameters of materials.

FIG. 4 is a schematic diagram of a detector assembly.

FIG. 5 is a schematic diagram of another detector assembly.

FIG. 6 is a schematic diagram of an embodiment of the detector assembly of FIG. 5.

FIG. 7 is a graph showing a plurality of HgZnTe layers producing a superlattice of HgZnTe for a HgZnTe mid wave detector layer.

FIG. 8 is a schematic diagram of another embodiment of the detector assembly of FIG. 5.

FIG. 9 is a graph showing a plurality of HgZnTe layers producing a superlattice of HgZnTe for a HgZnTe long wave detector layer.

FIG. 10 is a schematic diagram of another embodiment of the detector assembly of FIG. 5.

FIG. 11 is a graph showing alternating HgZnTe and HgCdTe layers to create a superlattice for a long wave detector layer.

FIG. 12 is a flow chart of a method of forming a detector assembly.

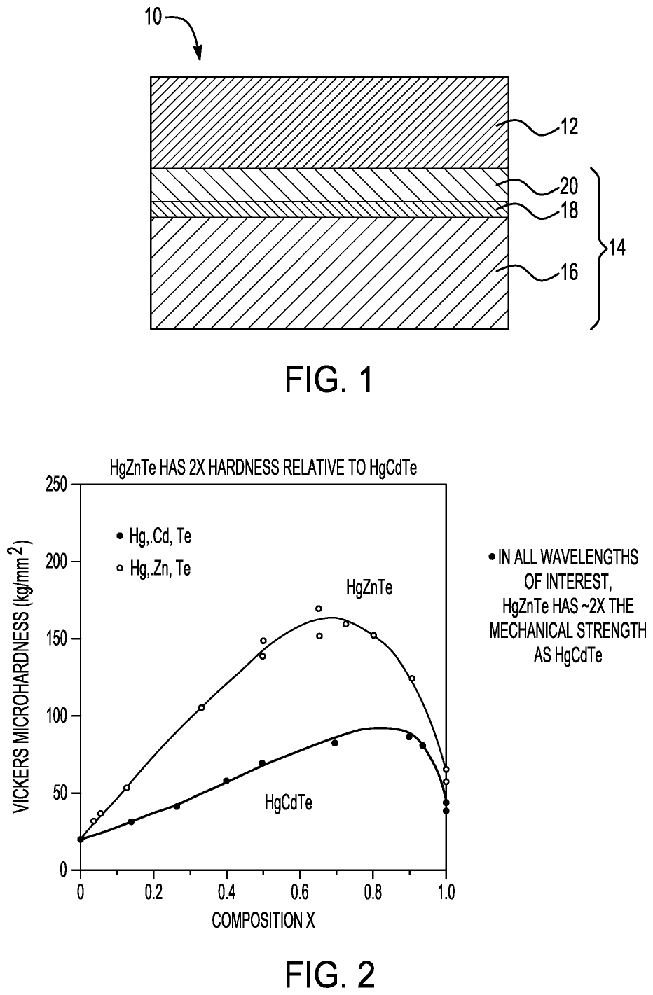

### DETAILED DESCRIPTION

With reference to FIG. 4, a detector assembly 22 configured to be used in a focal plane array uses a HgZnTe detector 24 on a substrate, for example a silicon substrate 26. The silicon substrate 26 may include, specifically, a silicon layer 28, a ZnTe buffer layer 30 and a CdTe buffer layer 32. The ZnTe buffer layer 30 and the CdTe buffer layer 30 may be grown by molecular-beam epitaxy (MBE). The HgZnTe detector 24 may be grown on the silicon substrate 26 by MBE.

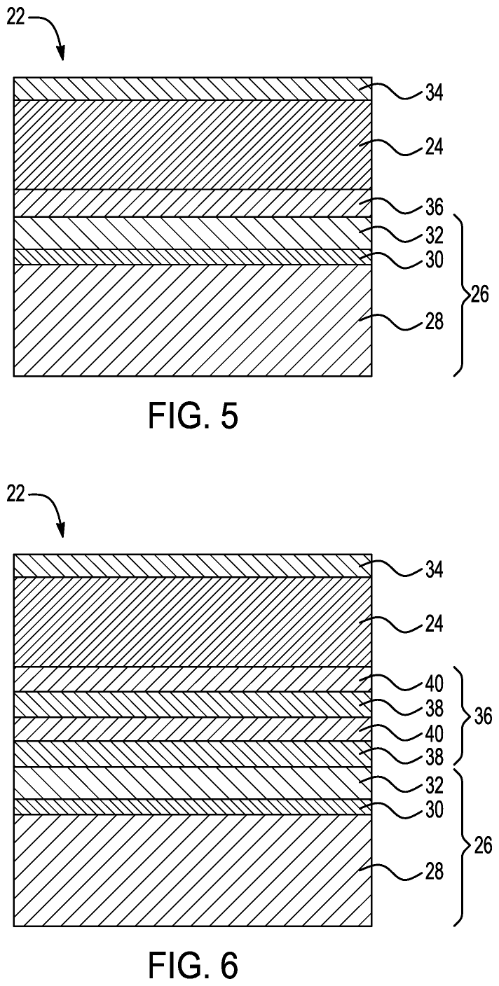

As depicted in FIG. 5, the detector assembly 22 may also include an MBE grown ZnTe passivation layer 34. That is, just as CdTe can be a passivation layer for HgCdTe, ZnTe may be a passivation layer to HgZnTe. The ZnTe passivation layer 34 may be grown in-situ with MBE or Metalorganic Chemical Vapor Deposition (MOCVD).

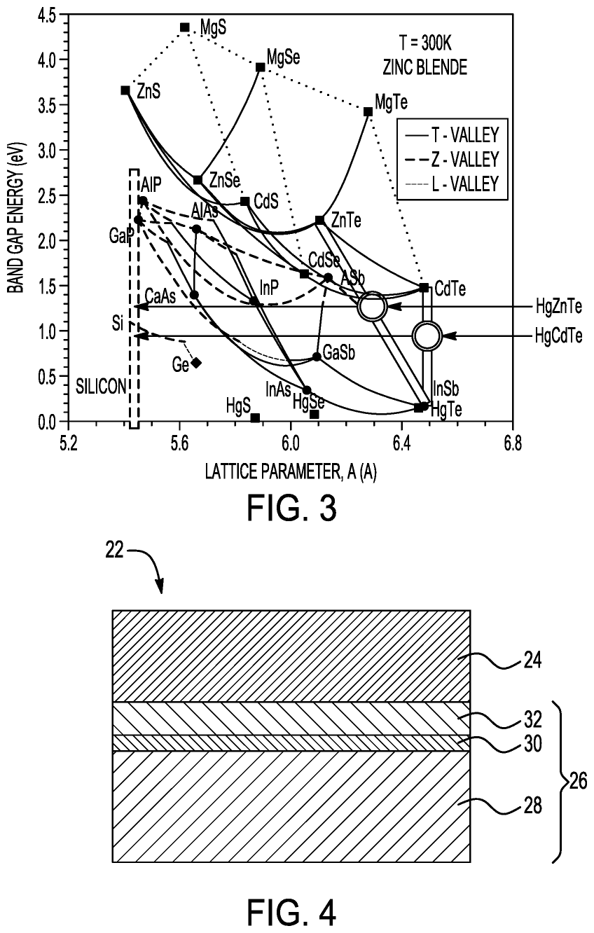

The detector assembly 22 may also include a HgZnTe-based buffer layer 36. For example, in one embodiment, the HgZnTe-based buffer layer 36 may include a strained layer superlattice of HgZnTe. That is, referring back to the graph of FIG. 3, the relationship between the lattice parameter of HgZnTe (represented by the line connecting the lattice parameter of HgTe and ZnTe) and the lattice parameter of silicon is variable and depends on the band energy gap. Specifically, the higher the band energy gap, the closer the lattice parameter of HgZnTe is to the lattice parameter of silicon. Therefore, two different layers of HgZnTe, having different band energy gaps, may be used to create the strained layer superlattice structure of HgZnTe used as the buffer layer 36. This is not possible with conventional HgCdTe detectors, as the relationship between the lattice parameter of HgCdTe and the lattice parameter of silicon does not change with band energy gap.

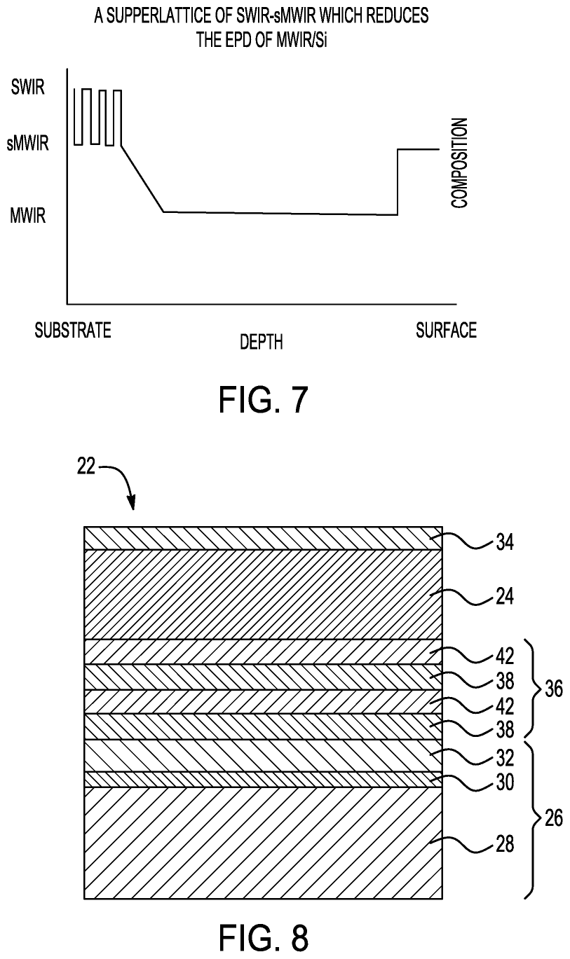

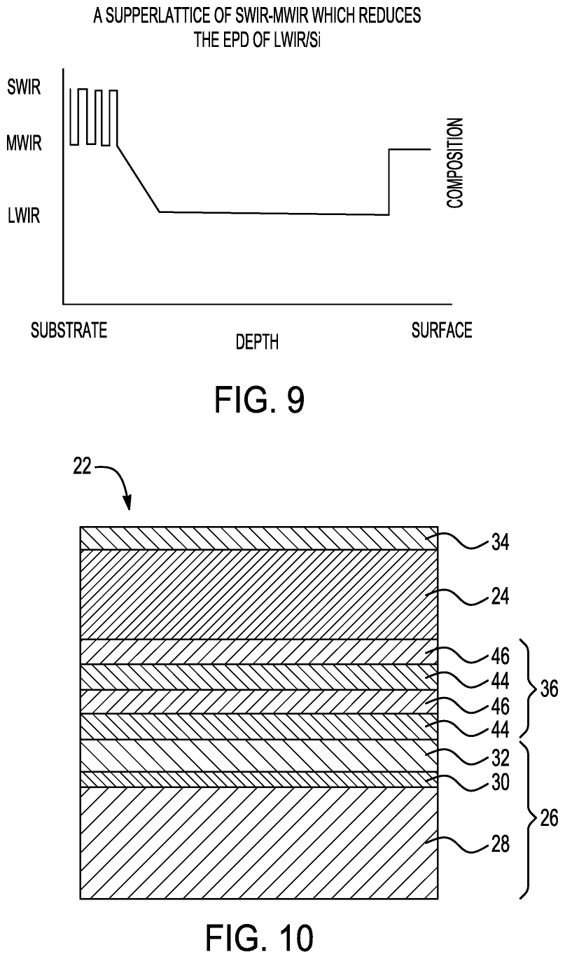

For example, with reference to FIGS. 6 and 7, a superlattice of at least one short-wave HgZnTe superlattice layer 38 and at least one short-medium-wave HgZnTe superlattice layer 40 (“SWIR-sMWIR”) may be used as the buffer layer 36 to reduce the EPD of a medium-wave HgZnTe detector 24 on the silicon substrate 26 (“MWIR/Si”). That is, by alternating between two compositions of HgZnTe, a superlattice is created. In this case, when layers of short-wave HgZnTe are sandwiched between short-medium-wave HgZnTe, a superlattice for medium-wave HgZnTe is created. The at least one short-wave HgZnTe superlattice layer 38 and the at least one short-medium-wave HgZnTe superlattice layer 40 may respectively include a plurality of short-wave HgZnTe superlattice layers 38 alternating with a plurality of short-medium-wave HgZnTe superlattice layers 40, as depicted in FIGS. 6 and 7. With reference to FIGS. 8 and 9, a superlattice of at least one short-wave HgZnTe superlattice layer 38 and at least one medium-wave HgZnTe superlattice layer 42 (“SWIR-MWIR”) may be used as the buffer layer 36 to reduce the EPD of a long-wave HgZnTe detector 24 on the silicon substrate 26 (“LWIR/Si”). That is, in this case, when layers of short-wave HgZnTe are sandwiched between medium-wave HgZnTe, a superlattice for long-wave HgZnTe is created. The at least one short-wave HgZnTe superlattice layer 38 and the at least one medium-wave HgZnTe superlattice layer 42 may respectively include a plurality of short-wave HgZnTe superlattice layers 38 alternating with a plurality of medium-wave HgZnTe superlattice layers 42, as depicted in FIGS. 8 and 9.

The compositional differences at the boundaries of the alternating layers of HgZnTe creates a strain field, which can then cause an upwardly moving dislocation to bend over laterally which will reduce the EPD in the HgZnTe detector 24. It takes a difference in lattice constant to create the interface strain layers capable of bending over dislocations. Accordingly, not only can long-wave detectors benefit, but also short-wave and medium-wave detectors can have reduced EPD with alternating layers of shorter wavelength HgZnTe below them.

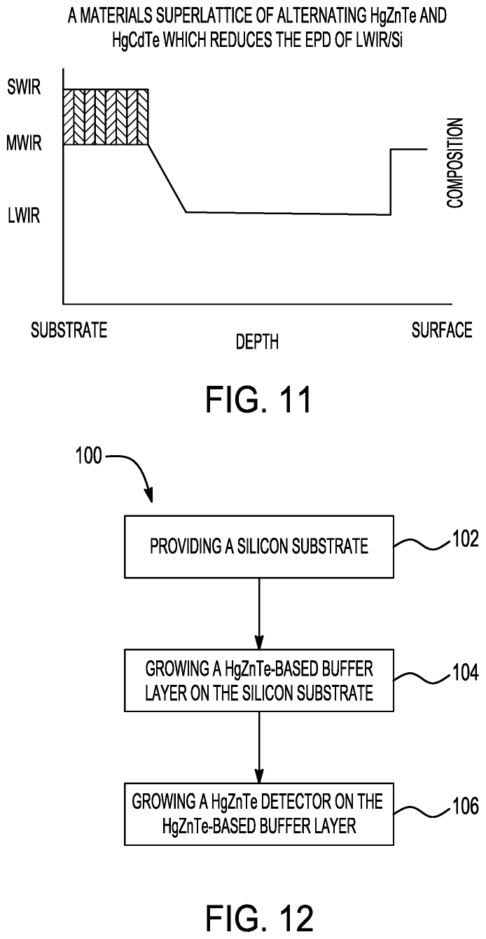

In an alternative embodiment, with reference to FIGS. 10 and 11, the HgZnTe-based buffer layer 36 may include a superlattice of at least one HgZnTe superlattice layer 44 and at least one HgCdTe superlattice layer 46. Providing at least one HgCdTe superlattice layer 46 between the silicon substrate 26 and the HgZnTe detector 24 may be beneficial as it provides a softer material below the much harder HgZnTe detector 24. For example, the superlattice may include a plurality of HgZnTe superlattice layers 44 respectively alternating with a plurality of HgCdTe superlattice layers 46, as depicted in FIGS. 10 and 11. This creates a buffer layer 36 having alternated hard layers (HgZnTe superlattice layers 44) and soft layers (HgCdTe superlattice layers 46) for additional reduction of EPD of the HgZnTe detector 34. Specifically, the superlattice of alternating HgZnTe superlattice layers 44 and HgCdTe superlattice layers 46 may be used to reduce the EPD of a short-wave HgZnTe detector, a medium-wave HgZnTe detector or a long-wave HgZnTe detector on the silicon substrate 26, as depicted (“LWIR/Si”). That is, when alternating layers of the same material are used for a superlattice, the only EPD reduction principle is the strain difference between layers as both layers will have the same hardness. However, by alternating harder HgZnTe with softer HgCdTe a second EPD reduction principle is created: the softer HgCdTe is more easily plastically deformed than the HgZnTe. A rising dislocation not only encounters a strain difference at the interface, but also encounters a softer material. This should increase the probability of the dislocation bending over to reduce the EPD in the detector layer. Such a structure is made by alternating HgZnTe with HgCdTe, grown by MBE or MOCVD.

Turning to FIG. 12, a method 100 of forming a detector assembly, such as the detector assembly 22 described above (FIGS. 4, 5, 6, 8 and 10), is depicted in a flow chart. The method 100 includes a step 102 of providing a silicon substrate, such as the silicon substrate 26 described above (FIGS. 4, 5, 6, 8 and 10). The method 100 then includes a step 104 of growing a HgZnTe-based buffer layer, such as the HgZnTe-based buffer layer 36 described above (FIGS. 4, 5, 6, 8 and 10) on the silicon substrate. Then, the method 100 includes a step 106 of growing a HgZnTe detector, such as the HgZnTe detector 24 described above (FIGS. 4, 5, 6, 8 and 10) on the HgZnTe-based buffer layer. The HgZnTe-based buffer layer and the HgZnTe detector may be grown using MBE or MOCVD.

The method 100 may further include a step of growing a passivation layer, such as the passivation layer 34 described above (FIGS. 4, 5, 6, 8 and 10) on the HgZnTe detector. The passivation layer may be grown using MBE as well.

The step 104 of growing the HgZnTe-based buffer layer on the silicon substrate may include growing a strained layer superlattice of at least one short-wave HgZnTe superlattice layer and at least one short-medium wave HgZnTe superlattice layer to create a HgZnTe-based buffer layer as described above with reference to FIGS. 6 and 7. Alternatively the step 104 of growing the HgZnTe-based buffer layer on the silicon substrate may include growing a strained layer superlattice of at least one short-wave HgZnTe superlattice layer and at least one medium-wave HgZnTe superlattice layer to create a HgZnTe-based buffer layer as described above with reference to FIGS. 8 and 9. In another embodiment, the step 104 of growing the HgZnTe-based buffer layer on the silicon substrate may include growing a superlattice of at least one HgZnTe superlattice layer and at least one HgCdTe superlattice layer to create a HgZnTe-based buffer layer as described above with reference to FIGS. 10 and 11.

It will be understood that although a silicon substrate is mentioned here for purposes of this disclosure, growing HgZnTe with either a HgZnTe superlattice or a HgZnTe and HgCdTe superlattice can be done on other substrate materials such as CdZnTe, Germanium, GaAs, and the like. HgZnTe with the unique superlattices presented here should have substantial benefits to devices made on silicon substrates, but the principles of the present disclosure are not limited to their application on silicon substrates alone.

Although the above disclosure has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments. In addition, while a particular feature may have been described above with respect to only one or more of several illustrated embodiments, such feature may be combined with one or more other features of the other embodiments, as may be desired and advantageous for any given or particular application.

What is claimed is:

1. A detector assembly, comprising:
a silicon substrate;
a HgZnTe-based buffer layer grown on the silicon substrate; and
a HgZnTe detector grown on the HgZnTe-based buffer layer.

2. The detector assembly according to claim 1, wherein the silicon substrate includes a silicon layer, a ZnTe layer and a CdTe layer.

3. The detector assembly according to claim 1, further comprising a passivation layer.

4. The detector assembly according to claim 3, wherein the passivation layer includes ZnTe.

5. The detector assembly according to claim 1, wherein any one of the HgZnTe-based buffer layer, the HgZnTe detector and the passivation layer are grown using molecular-beam epitaxy.

6. The detector assembly according to claim 1, wherein the HgZnTe-based buffer layer includes a strained layer superlattice of HgZnTe.

7. The detector assembly according to claim 1, wherein the HgZnTe-based buffer layer includes a strained layer superlattice of at least one short-wave HgZnTe superlattice layer and at least one short-medium wave HgZnTe superlattice layer.

8. The detector assembly according to claim 7, wherein the HgZnTe-based buffer layer includes a strained layer superlattice of a plurality of short-wave HgZnTe superlattice layers respectively alternating with a plurality of short-medium wave HgZnTe superlattice layers.

9. The detector assembly according to claim 1, wherein the HgZnTe-based buffer layer includes a strained layer superlattice of at least one short-wave HgZnTe superlattice layer and at least one medium-wave HgZnTe superlattice layer.

10. The detector assembly according to claim 9, wherein the HgZnTe-based buffer layer includes a strained layer superlattice of a plurality of short-wave HgZnTe superlattice layers respectively alternating with a plurality of medium-wave HgZnTe superlattice layers.

11. The detector assembly according to claim 1, wherein the HgZnTe-based buffer layer includes a superlattice of at least one HgZnTe superlattice layer and at least one HgCdTe superlattice layer.

12. The detector assembly according to claim 11, wherein the HgZnTe-based buffer layer includes a superlattice of a plurality of HgZnTe superlattice layers respectively alternating with a plurality of HgCdTe superlattice layers.

13. A method of forming a detector assembly, the method comprising the steps of:
providing a silicon substrate;
growing a HgZnTe-based buffer layer on the silicon substrate; and
growing a HgZnTe detector on the HgZnTe-based buffer layer.

14. The method according to claim 13, wherein the HgZnTe-based buffer layer is grown on the silicon substrate using molecular-beam epitaxy.

15. The method according to claim 13, wherein the HgZnTe detector is grown on the HgZnTe-based buffer layer using molecular-beam epitaxy.

16. The method according to claim 13, further comprising the step of growing a passivation layer on the HgZnTe detector.

17. The method according to claim 16, wherein the passivation layer is grown on the HgZnTe detector using molecular-beam epitaxy.

18. The method according to claim 13, wherein the growing the HgZnTe-based buffer layer on the silicon substrate includes growing a strained layer superlattice of at least one short-wave HgZnTe superlattice layer and at least one short-medium wave HgZnTe superlattice layer.

19. The method according to claim 13, wherein the growing the HgZnTe-based buffer layer on the silicon substrate includes growing a strained layer superlattice of at least one short-wave HgZnTe superlattice layer and at least one medium-wave HgZnTe superlattice layer.

20. The method according to claim 13, wherein the growing the HgZnTe-based buffer layer on the silicon substrate includes growing a superlattice of at least one HgZnTe superlattice layer and at least one HgCdTe superlattice layer.
